(19) United States
(12) Patent Application Publication
(10) Pub. No.: US 2010/0013030 A1
(43) Pub. Date: Jan. 21, 2010

(54) BIOSENSOR, MANUFACTURING METHOD THEREOF, AND BIOSENSING APPARATUS INCLUDING THE SAME

(75) Inventors: Han-Young Yu, Daejon (KR); An-Soon Kim, Daejon (KR); Chil-Seong Ah, Daejon (KR); Jong-Heon Yang, Daejon (KR); In-Bok Baek, Chungbuk (KR); Chang-Geun Ahn, Daejon (KR); Seong-Jae Lee, Daejon (KR); Jin-Ho Yun, Daejeon (KR)

Correspondence Address: LAHIVE & COCKFIELD, LLP;FLOOR 30, SUITE 3000, ONE POST OFFICE SQUARE, BOSTON, MA, 02109, US

(73) Assignee: Electronics and Telecommunicatins Research Institute, Daejeon (KR)

(21) Appl. No.: 12/443,376

(22) PCT Filed: Aug. 30, 2007
(86) PCT No.: PCT/KR07/04191

§ 371 Date: Mar. 27, 2009

(30) Foreign Application Priority Data
Sep. 27, 2006 (KR) 10-2006-0094397

(51) Int. Cl. H01L 29/66; H01L 21/30

(52) U.S. Cl. 257/414; 438/49; 257/E29.166; 257/E21.211

(57) ABSTRACT

Provided is a biosensor with a three-dimensional multi-layered structure, a method for manufacturing the biosensor, and a biosensing apparatus including the biosensor. The biosensing apparatus includes: a chamber having an inlet through which a fluid containing a biomaterial enters and an outlet through which the fluid exits; and a plurality of biosensors inserted and fixed in the chamber. Each biosensor includes: a support unit having a fluid channel through which a fluid containing a biomaterial flows; and a sensing unit disposed on the support unit in such a way that the sensing unit is exposed three-dimensionally in the fluid channel of the support unit, the sensing unit being surface-treated with a reactive material that is to react with the biomaterial flowing through the fluid channel.

### TECHNICAL FIELD

The present invention relates to a biosensor; and, more particularly, to a biosensor with a three-dimensional multi-layered structure, a method for manufacturing the biosensor, and a biosensing apparatus including the biosensor.

### BACKGROUND ART

A biosensor is a measurement device that uses a biochemical reaction to convert the concentration of a biochemical material in a living body into physical parameters, for example, an electrochemical parameter, an optical parameter, and a thermal parameter. Various biosensors are widely used to measure the concentrations of biochemical materials that are clinically valuable. What is most widely used among the various biosensors is an electrochemical biosensor that electrochemically senses a reaction between an enzyme and a target biochemical material. In light of the current technical level, a biosensor using an electrochemical reaction of an enzyme is evaluated as being most suitable for a sensor system that is inserted in the human body to quantitatively measure materials such as blood sugar, cholesterol, and lactate in the human body continuously for a long time.

In general, the electrochemical biosensor uses the following electrochemical methods. In an electrochemical method, a biomaterial adsorbed onto the biosensor is sensed by measuring a current of the biosensor that changes depending on an electric field of the biosensor that changes due to the adsorbed biomaterial. In another electrochemical method, a biomaterial adsorbed into a nanometer-sized gap is sensed by measuring a variation in the amount of a current of the biosensor, which is caused by the adsorption of the biomaterial.

FIG. 1 is a perspective view of a conventional biosensor. Referring to FIG. 1, the conventional biosensor includes a support unit 10, a sensing unit 13, and a cover 15. The sensing unit 13 is disposed across a top center of the support unit 10. The sensing unit 13 is surface-treated with a reactive material that will react with an entering biomaterial. The cover 15 covers the sensing unit 13. The cover 15 guides a biomaterial to a center portion 13A of the sensing unit 13 in the horizontal direction intersecting the sensing unit 13.

The sensing unit 13 is disposed on the support unit 10, and the cover 15 is disposed on the sensing unit 13 to protect the sensing unit 13. The support unit 10 includes a substrate 11, an insulating layer 12, and an additional insulating layer 14. The substrate 11 is formed of monocrystalline silicon. The insulating layer 12 is disposed on a top surface of the substrate 11, for electrical isolation of the support unit 10 from the sensing unit 13. The additional insulating layer 14 is disposed on a bottom surface of the substrate 11.

The cover 15 has a fluid channel 15A for guiding a biomaterial to the center portion 13A of the sensing unit 13 in the direction intersecting the sensing unit 13. The fluid channel 15A serves as a passage through which a biomaterial flows. The fluid channel 15A guides an entering biomaterial to the center portion 13A of the sensing unit 13.

In order to sense a biomaterial entering through the fluid channel 15A of the cover 15, the sensing unit 13 is surface-treated with a reactive material that will react with the entering biomaterial. The sensing unit 13 has a dumbbell-shaped structure. That is, the sensing unit 13 has the center portion 13A for detection of a biomaterial and left/right side portions 13B that are larger in width than the center portion 13A. As described above, the sensing unit 13 is disposed on the support unit 10 in the direction intersecting the fluid channel 15A.

An electrode 16 is disposed on each of the left/right side portions 13B of the sensing unit 13. The electrode 16 is connected with an external device to transmit a sense signal, which is sensed by the sensing unit 13, to the external device.

The operational characteristics of the conventional biosensor will be described below.

Referring to FIG. 1, when a target biomaterial enters through one end of the fluid channel 15A that is disposed horizontally in the cover 15, the biomaterial flows horizontally through the fluid channel 15A, intersects the center portion 13A of the sensing unit 13, and exits through the other end of the fluid channel 15A. While intersecting the sensing unit 13, the biomaterial is adsorbed onto three sides of the sensing unit 13. That is, the biomaterial is adsorbed onto only the top, left and right sides of the center portion 13A of the sensing unit 13 because the bottom side of the sensing unit 13 is covered with the top surface of the support unit 10. In the above adsorption process, the biomaterial reacts with the surface-treated reactive material of the sensing unit 13. This reaction causes a change in a current flowing through the sensing unit 13. This current change is measured through the electrode 16 to sense the biomaterial.

However, the conventional biosensor illustrated in FIG. 1 has the following limitations. First, because the sensing unit 13 is disposed in such a way as to horizontally intersect a biomaterial entering through the fluid channel 15A, the biomaterial is adsorbed onto only three sides of the sensing unit 13. The reason for this is that the bottom side of the sensing unit 13 is covered with the top surface of the support unit 10 and thus the biomaterial fails to contact the bottom side of the sensing unit 13. That is, the bottom side of the sensing unit 13 fails to sense the biomaterial. Moreover, because a flow rate of the biomaterial in the fluid channel 15A is higher at the center than at the bottom, the probability of the biomaterial being adsorbed onto the sensing unit 13 decreases accordingly.

Second, because the left/right sides of the sensing unit 13, which face the flow direction of the biomaterial entering through the fluid channel 15A, are smaller in area (i.e., width length) than the other sides of the sensing unit 13, the amount of a biomaterial adsorbed onto the sensing unit 13 decreases accordingly. In detail, the fluid channel 15A has a width/height of several tens to several hundreds of micrometers (μm), whereas the sensing unit 13 has a height ‘H’ of several tens of nanometers (nm) and a width ‘W’ of several tens to several hundreds of nanometers. Therefore, the probability of the biomaterial being adsorbed onto the sensing unit 13 is very low.

Third, the sensing unit 13 is provided in singularity in the conventional biosensor. Therefore, when a target biomaterial is changed, the sensing unit 13 must be again surface-treated with a reactive material capable of reacting with the changed biomaterial. This complicates the corresponding process and increases the total manufacturing process due to the additional surface treatment.

As described above, the conventional biosensor has the limitations due to the two-dimensional structure, such as a low biomaterial adsorption rate and an additional surface treatment for the changed biomaterial. What is therefore required is to develop a biosensor that has a three-dimensional multi-layered structure.

### DISCLOSURE OF INVENTION

### Technical Problem

An embodiment of the present invention is directed to providing a biosensor that can provide an increased biomaterial adsorption rate.

Another embodiment of the present invention is directed to providing a biosensor that can simultaneously sense various biomaterials contained in a fluid.

A further embodiment of the present invention is directed to providing a biosensing apparatus with a plurality of biosensors that can simultaneously sense various biomaterials contained in a fluid.

A still further embodiment of the present invention is directed to providing a method for manufacturing the above biosensor.

Other objects and advantages of the present invention can be understood by the following description, and become apparent with reference to the embodiments of the present invention. Also, it is obvious to those skilled in the art of the present invention that the objects and advantages of the present invention can be realized by the means as claimed and combinations thereof.

### Technical Solution

In accordance with an aspect of the present invention, there is provided a biosensor including: a support unit having at least one fluid channel through which a fluid containing a biomaterial flows; and at least one sensing unit disposed on the support unit in such a way that the sensing unit is exposed three-dimensionally in the fluid channel of the support unit, the sensing unit being surface-treated with a reactive material that is to react with the biomaterial flowing through the fluid channel.

In accordance with another aspect of the present invention, there is provided a biosensing apparatus including: a chamber having an inlet through which a fluid containing a biomaterial enters and an outlet through which the fluid exits; and a plurality of biosensors inserted and fixed in the chamber, each of the biosensors including: a support unit having a fluid channel through which a fluid containing a biomaterial flows; and a sensing unit disposed on the support unit in such a way that the sensing unit is exposed three-dimensionally in the fluid channel of the support unit, the sensing unit being surface-treated with a reactive material that is to react with the biomaterial flowing through the fluid channel.

In accordance with another aspect of the present invention, there is provided a method for fabricating a biosensor, the method including the steps of: forming an insulating layer on a top surface of a substrate; depositing a sensing unit material on the insulating layer; forming an etch barrier layer on a bottom surface of the substrate; etching the etch barrier layer to expose a portion of the bottom surface of the substrate; etching the substrate and the insulating layer using the etch barrier layer as an etching mask, to form a fluid channel exposing a portion of the sensing unit material; and etching the sensing unit material to form a sensing unit intersecting the fluid channel.

In the conventional biosensor, the fluid channel is formed across the sensing unit for sensing a biomaterial. However, the conventional biosensor has a two-dimensional structure in which one side of the sensing unit is covered with the support unit. Therefore, the biomaterial is adsorbed onto only three sides of the sensing unit in the conventional biosensor.

The present invention provides a biosensor having a three-dimensional structure in which a biomaterial can be adsorbed onto four sides of a sensing unit and a method for manufacturing the biosensor. In accordance with the present invention, a fluid channel is formed vertically or horizontally at a center portion of a support unit, and the sensing unit is disposed on and across the fluid channel in such a way that none of the four sides of the sensing unit is covered with the support unit. Accordingly, a biomaterial flowing through the fluid channel can be adsorbed onto all of the four sides of the sensing unit.

The sensing unit is surface-treated with a reactive material that will react with a biomaterial. Herein, the biomaterial corresponds to an antigen containing nucleic acid and protein, and the reactive material corresponds to an antibody that reacts with the antigen.

### ADVANTAGEOUS EFFECTS

First, in accordance with the present invention, the fluid channel is formed vertically or horizontally at the center portion of the support unit, and the sensing unit is disposed on and across the fluid channel in such a way that none of the four sides of the sensing unit is covered with the support unit. Accordingly, the biomaterial flowing through the fluid channel can be adsorbed onto all of the four sides of the sensing unit and thus the capability of sensing the biomaterial can be further enhanced.

Second, in accordance with the present invention, a plurality of biosensors whose sensing units are surface-treated with a variety of different reactive material are inserted and fixed in series in one chamber. Accordingly, it is possible to simultaneously sense various biomaterials contained in a fluid flowing through the fluid channel.

### BRIEF DESCRIPTION OF THE DRAWINGS

FIG. 1 is a perspective view of a conventional biosensor.

FIG. 2 is a perspective view of a biosensor in accordance with a first embodiment of the present invention.

FIG. 3 is a schematic view illustrating the operational characteristics of the biosensor illustrated in FIG. 2.

FIGS. 4 to 9 are perspective views illustrating a method for manufacturing the biosensor illustrated in FIG. 2.

FIG. 10 is a perspective view of a biosensor in accordance with a second embodiment of the present invention.

FIG. 11 is a perspective view of a biosensing apparatus with a plurality of biosensors in accordance with a third embodiment of the present invention.

FIG. 12 is a perspective view illustrating the biosensor and a connecting member illustrated in FIG. 11.

### BEST MODE FOR CARRYING OUT THE INVENTION

The advantages, features and aspects of the invention will become apparent from the following description of the embodiments with reference to the accompanying drawings, which is set forth hereinafter. Like reference numerals denote like elements throughout the specification.

### Embodiment 1

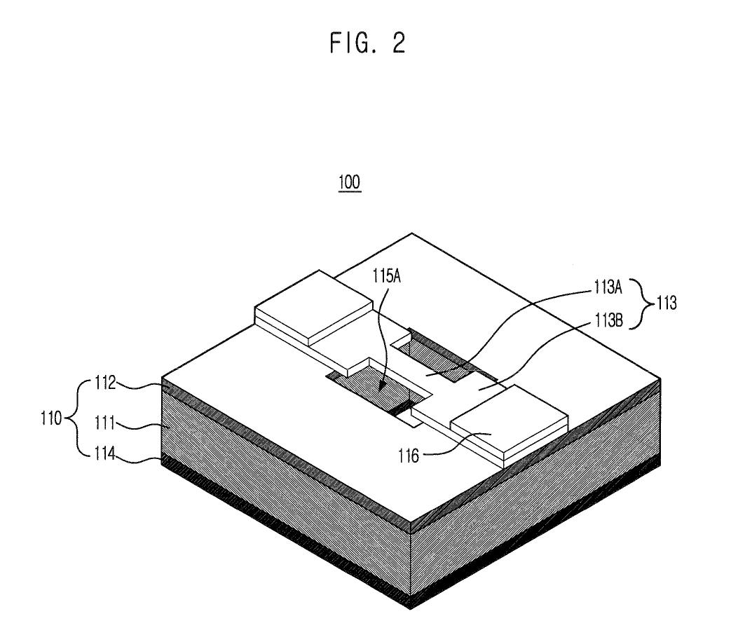

FIG. 2 is a perspective view of a biosensor in accordance with a first embodiment of the present invention. Hereinafter, the biosensor in accordance with the first embodiment of the present invention will be described with reference to FIG. 2.

Referring to FIG. 2, a biosensor 100 includes a support unit 110 and a sensing unit 113. A center portion of the support unit 110 is vertically perforated to form a fluid channel 115A through which a biomaterial flows. The sensing unit 113 is disposed across the fluid channel 115A of the support unit 110. The sensing unit 113 is surface-treated with a reactive material that will react with a biomaterial flowing through the fluid channel 115A.

The support unit 110 includes a substrate 111, an etch barrier layer 114 disposed on a bottom surface of the substrate 111, and an insulating layer 112 disposed on a top surface of the substrate 111. The fluid channel 115A is formed through the center portions of the substrate 111, the etch barrier layer 114, and the insulating layer 112.

The topside of the substrate 111 has a flat-plate structure in order to support the sensing unit 113 stably. For example, the substrate 111 may be formed of monocrystalline silicon, glass, or plastic.

The etch barrier layer 114 serves as a hard mask for preventing the other portions of the substrate 111, except a portion destined for the fluid channel 115A, from being damaged during an etch process for forming the fluid channel 115A in the substrate 111. Preferably, the etch barrier layer 114 may be formed of a material having a high etch selectivity with respect to the material of the substrate 111. For example, when the substrate 111 is formed of monocrystalline silicon, the etch barrier layer 114 may be formed of a nitride material such as silicon nitride (SiN). Alternatively, the etch barrier layer 114 may be formed of an oxide material such as silicon oxide (SiO₂).

The insulating layer 112 may be formed of an oxide material for preventing an electrical short between the substrate 111 and the sensing unit 113. Preferably, the insulating layer 112 is formed of silicon oxide. Alternatively, the insulating layer 112 may be formed of a non-conductive nitride material such as silicon nitride.

The sensing unit 113 is surface-treated with a reactive material reacting with a biomaterial, in order to sense a biomaterial entering through the fluid channel 115A of the support unit 110. For example, the sensing unit 113 is shaped like a dumbbell. The dumbbell-shaped sensing unit 113 has a center portion 113A and left/right side portions 113B. The center portion 113A has a relatively small width and serves to sense a biomaterial in actuality. Each of the left/right side portions 113B has a larger width than the center portion 113A and serves as a channel for transmitting a sensing signal of the center portion 113A to an electrode 116. The sensing unit 113 is disposed across the fluid channel 115A on the top center of the support unit 110.

The electrode 116 is disposed on each of the left/right side portions 113B of the sensing unit 113. The electrode 116 is connected to an external device to transmit a sensing signal of the sensing unit 113 to the external device.

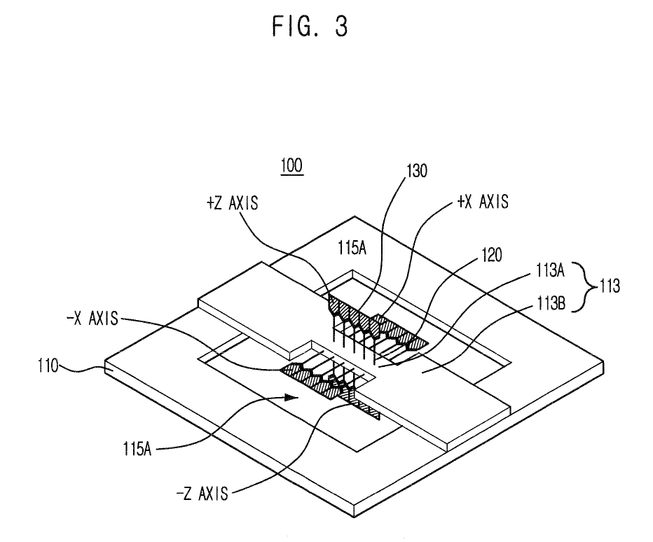

FIG. 3 is a schematic view of the biosensor 100 illustrated in FIG. 2. Hereinafter, the operational characteristics of the biosensor 100 in accordance with the first embodiment of the present invention will be described with reference to FIG. 3.

Referring to FIG. 3, first, a reactive material 120 that will react with a target biomaterial is adsorbed onto the sensing unit 113 by surface treatment. Thereafter, when a material including a biomaterial enters through one end of the fluid channel 115A vertically piercing the support unit 110, the biomaterial flows vertically through the fluid channel 115A, intersects the center portion 113A of the sensing unit 113, and exits through the other end of the fluid channel 115A. While intersecting the sensing unit 113, a biomaterial 130 is adsorbed onto four sides of the sensing unit 113 in +Z axis, −Z axis, −X axis, and +X axis directions. In this adsorption process, the biomaterial reacts chemically with the reactive material 120 adsorbed onto the sensing unit 113. This chemical reaction causes a change in a current flowing through the sensing unit 113. This current change is measured through the electrode 116 to sense the biomaterial 130.

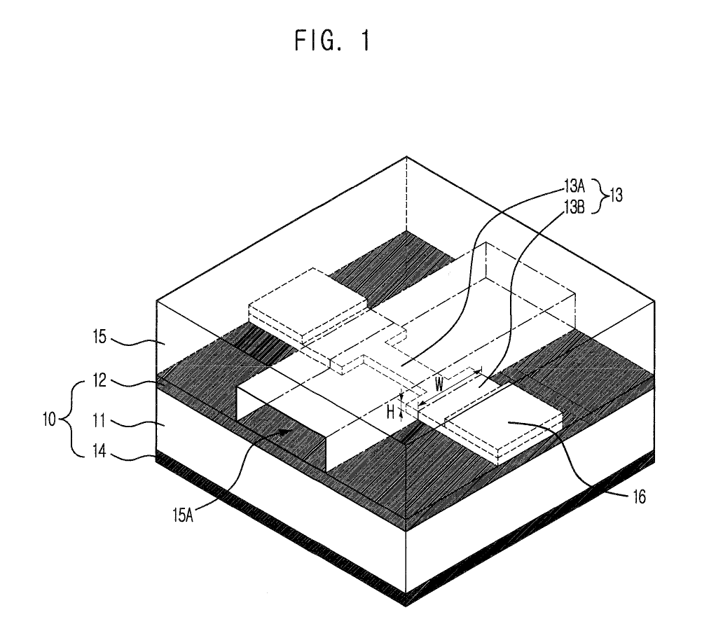

As described with reference to FIGS. 2 and 3, the biosensor 100 in accordance with the first embodiment of the present invention is manufactured in a three-dimensional structure in such as way that the biomaterial is adsorbed onto the four sides of the sensing unit 113. Therefore, the biosensor 100 in accordance with the first embodiment of the present invention can greatly increase the biomaterial adsorption area when compared to the conventional two-dimensional biosensor illustrated in FIG. 1. In addition, the biosensor 100 in accordance with the first embodiment of the present invention can enhance the capability of sensing the biomaterial by increasing the frequency of contacts between the biomaterial and the sensing unit 113 when the fluid containing the biomaterial intersects the center portion 113A of the sensing unit 113.

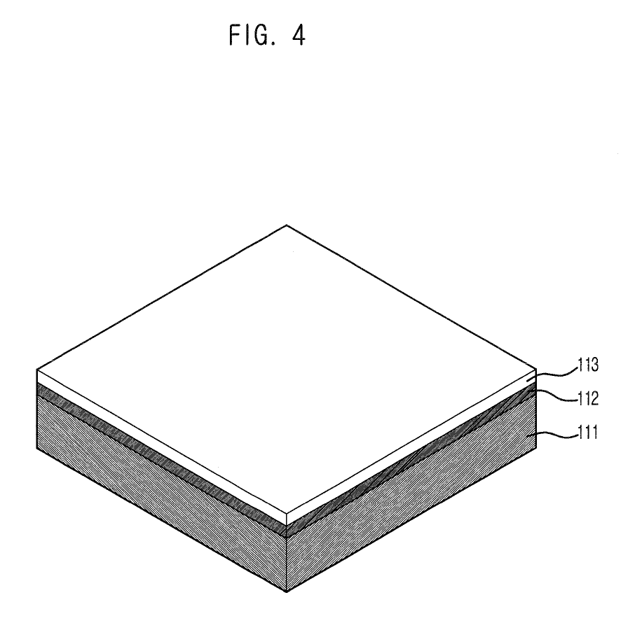

FIGS. 4 to 9 are perspective views illustrating a method for manufacturing the biosensor 100 illustrated in FIG. 2. Hereinafter, a method for manufacturing the biosensor 100 in accordance with the first embodiment of the present invention illustrated in FIG. 2 will be described with reference to FIGS. 4 to 9.

Referring to FIG. 4, a substrate 111 is prepared. At this point, the substrate 111 may be formed of monocrystalline silicon, glass, or plastic that is widely used in a semiconductor fabrication process.

Thereafter, an insulating layer 112 is deposited on the substrate 111. At this point, the insulating layer 112 may be deposited using a chemical vapor deposition (CVD) process or a physical vapor deposition (PVD) process. Alternatively, the insulating layer 112 may be coated using a spin-coating process. The insulating layer 112 may be a single layer or two or more stacked layers that is/are formed of an oxide material or a non-conductive nitride material in order to electrically isolate the substrate 111 from a sensing unit 113 (see FIG. 2) that will be formed in the subsequent process.

Examples of the oxide material include High Density Plasma (HDP), Boron Phosphorus Silicate Glass (BPSG), Phosphorus Silicate Glass (PSG), Plasma Enhanced Tetra Ethyle Ortho Silicate (PETEOS), Un-doped Silicate Glass (USG), Fluorinated Silicate Glass (FSG), Carbon Doped Oxide (CDO), and Organo Silicate Glass (OSG). Examples of the nitride material include silicon nitride.

Thereafter, a sensing unit material 113, which is denoted using the same reference numeral as the sensing unit 113 for convenience in description, is deposited on the insulating layer 112. At this point, the sensing unit material 113 may be any material whose electrical characteristics can change depending on an external electric field. Examples of the sensing unit material 113 include crystalline silicon, amorphous silicon, and doped silicon. At this point, the doped silicon is doped with n-type or p-type impurities.

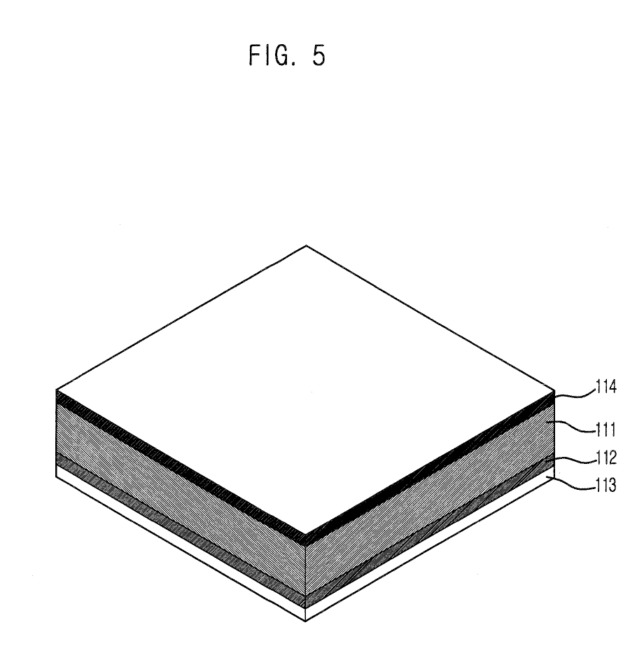

Referring to FIG. 5, the substrate 111 is turned upside down such that a bottom surface of the substrate 111 is directed upward. Thereafter, an etch barrier layer 114 is deposited on the bottom surface of the substrate 111. At this point, the etch barrier layer 114 is formed of a material having a predetermined etch selectivity with respect to the insulating layer 112. For example, when the insulating layer 112 is formed of an oxide material, the etch barrier layer 114 is formed of a nitride material. On the contrary, when the insulating layer 112 is formed of a nitride material, the etch barrier layer 114 is formed of an oxide material.

Although not illustrated, the etch barrier layer 114 may also be deposited on a top surface of the substrate 111. This is to prevent the insulating layer 112, which has been deposited on the substrate 111, from being damaged by an etching solution when the etch barrier layer 114 is subsequently etched using a wet etching process. In general, the wet etching process is performed in such a way that the entire surface of the substrate 111 is immersed in the etching solution. In this case, not only the bottom surface of the substrate 111 but also the insulating layer 112, which has been deposited on the top surface of the substrate 111, are exposed to and damaged by the etching solution. In order to prevent this, if a wet etching process is used to perform the subsequent etching process, the etch barrier layer 114 needs to be deposited also on the top surface of the substrate 111. On the other hand, if a dry etching process using an etching gas is used to perform the subsequent etching process, the etch barrier layer 114 may be deposited only on the bottom surface of the substrate 111.

Thereafter, a photoresist layer (not illustrated) is coated on the etch barrier layer 114 and then an exposure/development process using a photomask is performed to form a photoresist layer pattern (not illustrated).

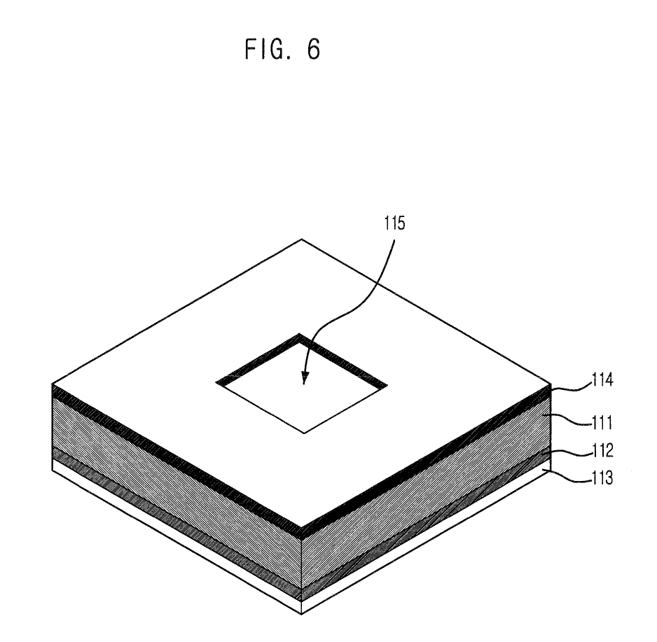

Thereafter, using the photoresist layer pattern as an etching mask, an etching process is performed to etch the etch barrier layer 114. At this point, it is preferable that the etching process is performed using a dry etching process. The dry etching process is performed under etching conditions considering an etch selectivity between the substrate 111 and the etch barrier layer 114, thereby etching the etch barrier layer 114 selectively. Referring to FIG. 6, a hole 115 is formed at a center portion of the etch barrier layer 114 to expose a portion of the bottom surface of the substrate 111.

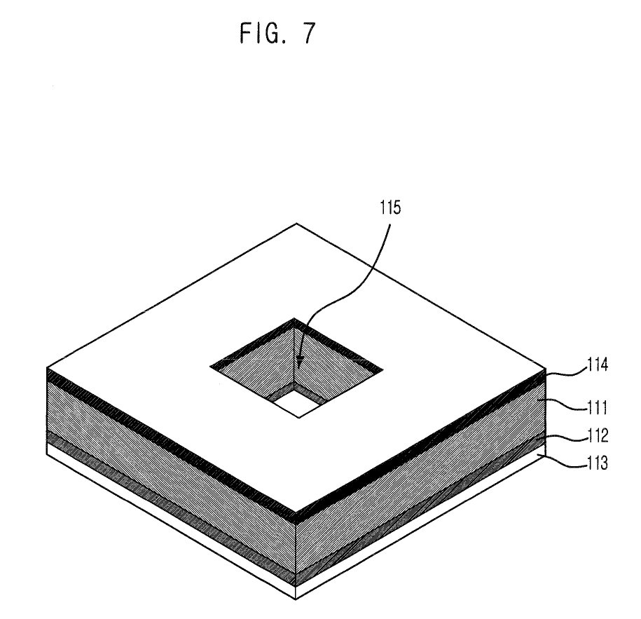

Referring to FIG. 7, using the photoresist layer pattern as an etching mask, an etching process is performed to sequentially etch the substrate 111 and the insulating layer 112, which are exposed through the hole 115. In result, a fluid channel 115A is formed to expose the sensing unit material 113.

Alternatively, after removal of the photoresist layer pattern, using the etch barrier layer 114 as an etching mask, an etching process is performed to sequentially etch the substrate 111 and the insulating layer 112. In this case, it is preferable that an etching process with a high etch selectivity between the etch barrier layer 114 and the substrate 111 is performed to etch only the substrate 111 and the insulating layer 112 selectively.

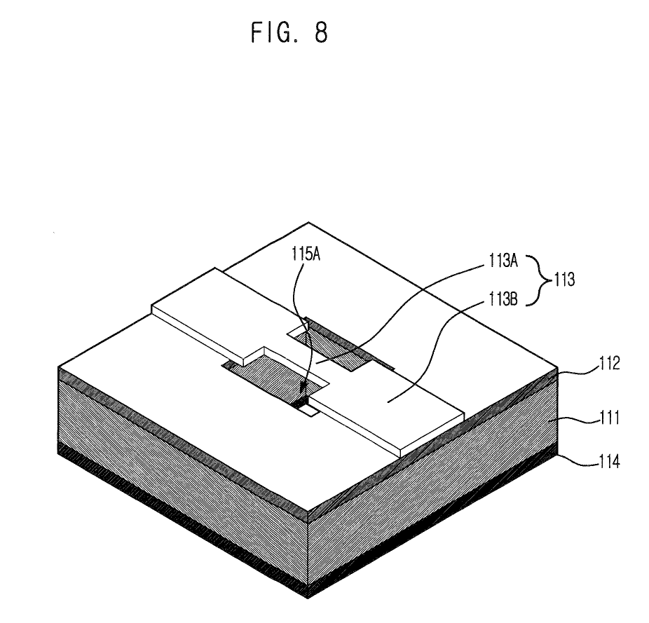

Referring to FIG. 8, the substrate 111 is turned upside down such that the top surface of the substrate 111 is directed upward. Thereafter, a photoresist layer is coated on the sensing unit material 113 and then an exposure/development process is performed to form a photoresist layer pattern (not illustrated).

Thereafter, using the photoresist layer pattern as an etching mask, an etching process is performed to etch the sensing unit material 113, thereby forming a sensing unit 113. The sensing unit 113 is shaped like a dumbbell. That is, the sensing unit 113 has a center portion 113A that intersects the fluid channel 115A and left/right side portions 113B that are superimposed on the insulating layer 112, and the center portion 113A is smaller in width than the left/right side portions 113B.

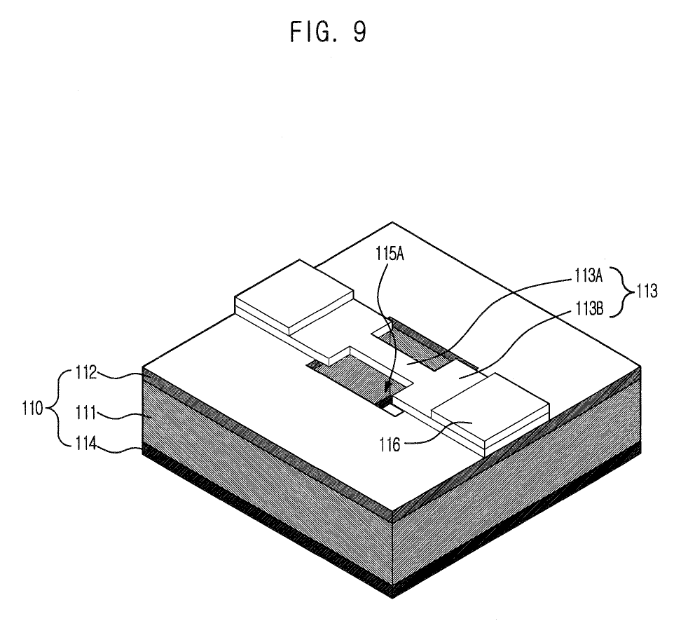

Referring to FIG. 9, an electrode material 116, which is denoted using the same reference numeral as an electrode 116 for convenience in description, is deposited on the resulting structure including the sensing unit 113. The electrode material 116 may be one metallic material selected from the group consisting of aluminum (Al), copper (Cu), ruthenium (Ru), titanium (Ti), tantalum (Ta), tungsten (W) hafnium (Hf), zirconium (Zr), platinum (Pt), and iridium (Ir). Alternatively, the electrode material 116 may be one nitride material selected from the group consisting of titanium nitride (TiN), tantalum nitride (TaN), tungsten nitride (WN), and zirconium nitride (ZrN). Further alternatively, the electrode material 116 may be a stack of a metallic material and an oxide material, such as ruthenium/ruthenium oxide (Ru/RuO₂) and iridium/iridium oxide (Ir/IrO₂). Further alternatively, the electrode material 116 may be an oxide material such as strontium ruthenium oxide (SrRuO₃). Further alternatively, the electrode material 116 may be a metal silicide material such as cobalt silicide (CoSi₂) and titanium silicide (TiSi₂).

Thereafter, an etching mask is formed and then an etching process using the etching mask is performed to etch the electrode material 116. In result, an electrode 116 is formed on each of the left/right side portions 113B of the sensing unit 113.

Thereafter, through the fluid channel 115A, a reactive material 120 (see FIG. 3) capable of reacting with a target biomaterial is flowed and adsorbed onto the center portion 113A of the sensing unit 113.

The biosensor is completed through the above processes.

### Embodiment 2

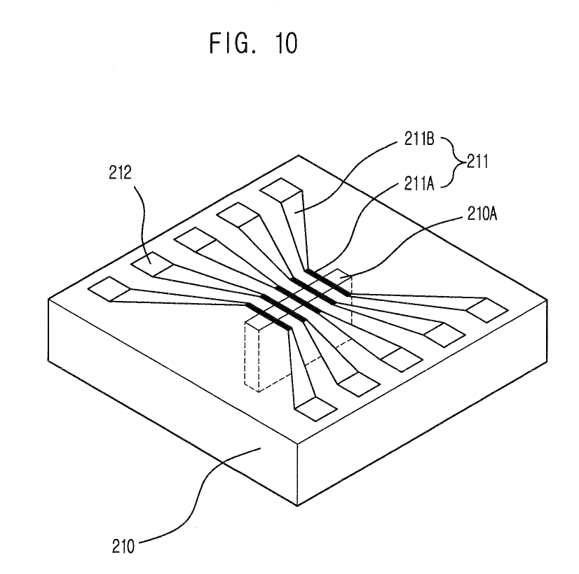

FIG. 10 is a perspective view of a biosensor in accordance with a second embodiment of the present invention.

Referring to FIG. 10, the biosensor in accordance with the second embodiment of the present invention is manufactured in the similar way as the biosensor in accordance with the first embodiment of the present invention. One sensing unit 113 intersects one fluid channel 115A in the first embodiment, whereas a plurality of sensing units 211 intersect one fluid channel 210A in the second embodiment. Therefore, compared to the first embodiment, the second embodiment can increase the total area of the sensing unit, onto which a biomaterial flowing through the fluid channel is to be adsorbed, thereby enhancing the capability of sensing the biomaterial.

In addition, a variety of different reactive materials may be adsorbed respectively onto a plurality of sensing units 211. In this case, even when a fluid containing various biomaterials enters through the fluid channel 210A, the various biomaterials can be simultaneously sensed using the sensing units 211 onto which a variety of different reactive materials are adsorbed.

In FIG. 10, a reference numeral 210 denotes a support unit. A reference numeral 212 denotes an electrode. A reference numeral ‘211A’ denotes a center portion of the sensing unit 211, onto which a biomaterial is actually adsorbed. A reference numeral ‘211B’ denotes left/right side portions of the sensing unit 211, which transmits a sense signal sensed by the center portion 211A of the sensing unit 211 to the electrode 212.

### Embodiment 3

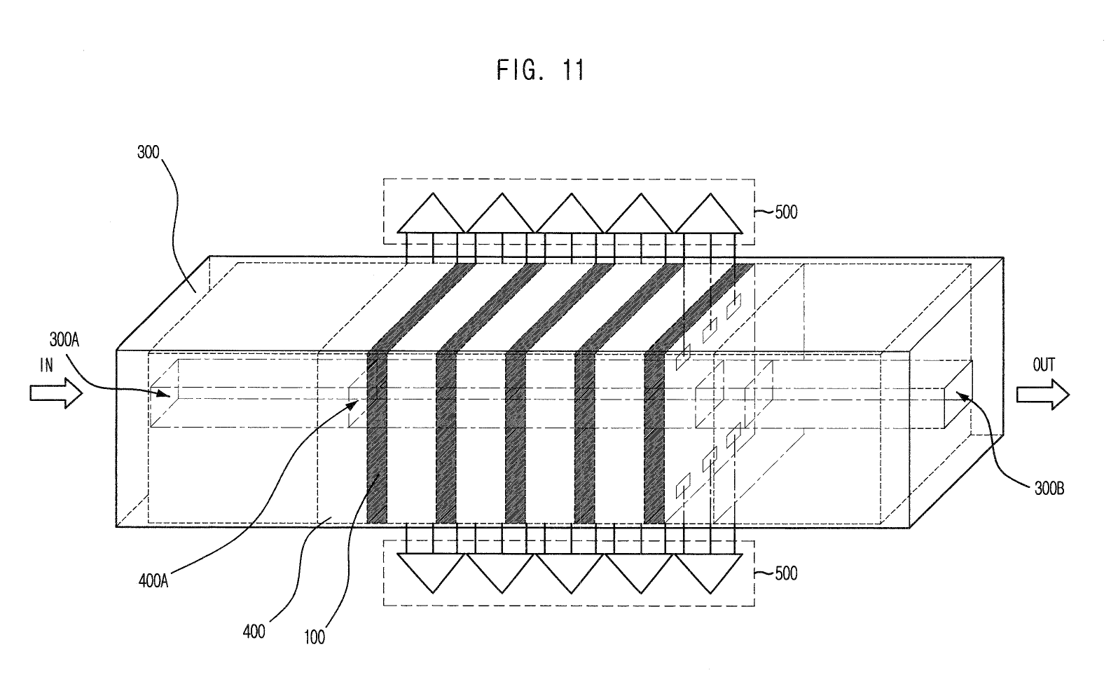

FIG. 11 is a perspective view of a biosensing apparatus with a plurality of biosensors in accordance with a third embodiment of the present invention. Like elements in FIGS. 2 and 11 are denoted by like reference numerals and their detailed description are omitted for conciseness.

Referring to FIG. 11, a biosensing apparatus in accordance with the third embodiment of the present invention includes a chamber 300, a plurality of biosensors 100, and a connecting member 400. The chamber 300 has an inlet 300A and an outlet 300B facing each other such that a fluid containing a biomaterial enters through one end of the chamber 300 and then exists through the other end of the chamber 300. The biosensors 100 are inserted and fixed in series in the chamber 300 such that a fluid channel 115A (see FIG. 2) is disposed to face the inlet 300A and the outlet 300B. The connecting member 400 has a through hole 400A at a portion corresponding to the fluid channel 115A, to adhesively connect the neighboring biosensors 100.

The chamber 300 has a rectangular structure. The chamber 300 has the inlet 300A at one longitudinal end thereof and the outlet 300B at the other end thereof. The biosensors 100 are inserted and fixed between the inlet 300A and the outlet 300B of the chamber 300. The structure of the chamber 300 is not limited to a rectangular structure. That is, the chamber 300 may have various structures such as triangle, square, hexagon, octagon and circle, depending on the shape of the biosensor 100.

The connecting member 400 has the same periphery as the biosensor 100 so that the connecting member 400 can be inserted and fixed in the chamber 300, together with the biosensor 100. The connecting member 400 has the through hole 400A at a portion facing the inlet 300A and the outlet 300B. When the connecting member 400 is completely inserted in the chamber 300, the through hole 400A of the connecting member 400 is located on the same line as the inlet 300A and the outlet 300B.

The connecting member 400 may be implemented using only an adhesive material for adhesively connecting the neighboring biosensors 100 simply and conveniently. Alternatively, the connecting member 400 may be implemented using a structure that is surface-treated with the adhesive material. The structure for the connecting member 400 may be formed of a semiconductor material. Alternatively, the connecting member 400 may be implemented using a non-adhesive structure.

The connecting member 400 may be implemented using a soft material such as Poly-Dimethyl Siloxane (PDMS) in order to enhance the device flexibility and stability.

The adhesive material may be any hydrophilic material including molecules. For example, the molecule-containing hydrophilic material may be any silane-based compound such as AminoPropylTriEthoxySilane (APTES) and (3-AminoPropyl) TriMethoxySilane (APTMS).

The biosensors 100 are unitary biosensors illustrated in FIGS. 2 and 10. The biosensors 100 can be surface-treated with different reactive materials, thereby making it possible to simultaneously sense various biomaterials entering through the biosensing apparatus.

Referring to FIG. 11, the biosensing apparatus in accordance with the third embodiment of the present invention further includes a measuring unit 500 for measuring a sense signal output from each of the biosensors 100. Herein, the sense signal corresponds to a variation in the amount of a current flowing through a sensing unit 113 (see FIG. 2) of the biosensor 100, which is caused by a chemical reaction between a biomaterial and a reactive material 120 (see FIG. 3) adsorbed onto the sensing unit 113.

Hereinafter, the operational characteristics of the biosensing apparatus in accordance with the third embodiment of the present invention will be described with reference to FIG. 11.

Referring to FIG. 11, when a fluid containing various biomaterials or a fluid containing a biomaterial enters through the inlet 300A of the chamber 300, the fluid passes through the through holes 400A of alternate connecting members 400 and the fluid channels 115A (see FIG. 2) of the biosensors 100 and then exits through the outlet 300B of the chamber 300. At this point, because the sensing units 113 (see FIG. 2) of the biosensors 100 are surface-treated with various reactive materials that react with various biomaterials, the biomaterial contained in the fluid flowing through the fluid channel 115A is adsorbed onto the sensing unit 113 (see FIG. 2) of the biosensor 100, which is surface-treated with the corresponding reactive material. This adsorption process causes a variation in the amount of a current flowing through the sensing unit 113, and such a current variation is measured by the measuring unit 500.

As described above, the biosensing apparatus in accordance with the third embodiment of the present invention has a plurality of the biosensors inserted and fixed in series in the chamber, whose sensing units are surface-treated with a variety of different reactive materials, thereby making it possible to simultaneously sense various biomaterials contained in the fluid flowing through the fluid channel.

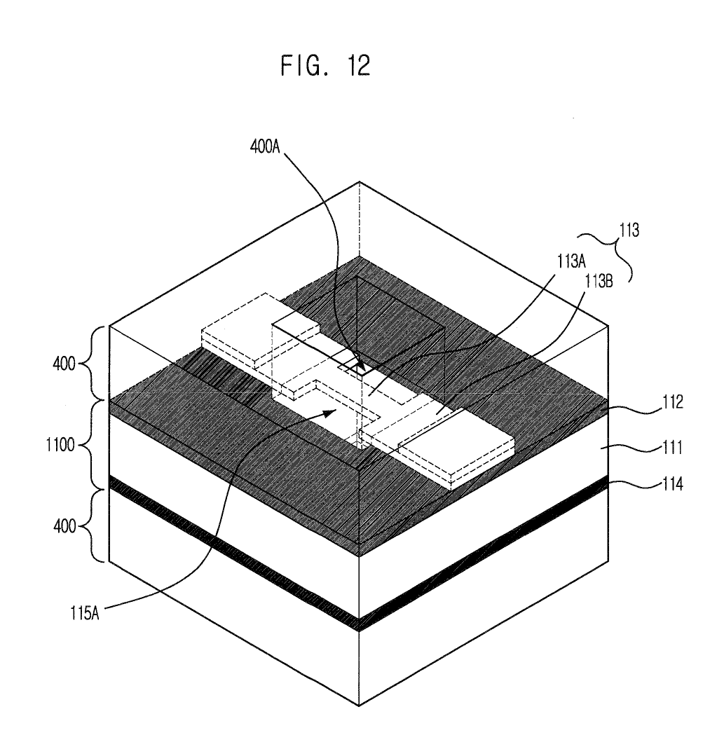

FIG. 12 is a perspective view illustrating the condition where the biosensor 100 and the connecting member 400 are connected with each other in the biosensing apparatus in accordance with the third embodiment illustrated in FIG. 11.

Although the description has been given of the use of a single semiconductor substrate such as a Si substrate and a Ge substrate in the above embodiments, a Silicon-On-Insulator (SOI) substrate can also be used instead of the single semiconductor substrate. Because the SOI substrate has a buried silicon oxide layer, the SOI substrate does not require an additional insulating layer and the isolation of a device from the SOI substrate can be secured when the device is formed on the SOI substrate. Therefore, a leakage current between devices can be reduced and thus the operational characteristics can be improved. The SOI substrate can be manufactured u sing various processes such as Silicon-On-Sapphire (SOS) and Separation-by-IMplanted-OXygen (SIMOX).

As described above, the present invention can provide the following effects.

First, the fluid channel is formed vertically or horizontally at the center portion of the support unit, and the sensing unit is disposed on and across the fluid channel in such a way that none of the four sides of the sensing unit is covered with the support unit. Accordingly, the biomaterial flowing through the fluid channel can be adsorbed onto all of the four sides of the sensing unit and thus the capability of sensing the biomaterial can be further enhanced.

Second, a plurality of biosensors whose sensing units are surface-treated with a variety of different reactive material are inserted and fixed in series in one chamber. Accordingly, it is possible to simultaneously sense various biomaterials contained in a fluid flowing through the fluid channel.

The present application contains subject matter related to Korean Patent Application No. 2006-0094397, filed in the Korean Intellectual Property Office on Sep. 27, 2006, the entire contents of which is incorporated herein by reference.

While the present invention has been described with respect to the specific embodiments, it will be apparent to those skilled in the art that various changes and modifications may be made without departing from the spirit and scope of the invention as defined in the following claims.

1. A biosensor comprising:
a support unit having at least one fluid channel through which a fluid containing a biomaterial flows; and
at least one sensing unit disposed on the support unit in such a way that the sensing unit is exposed three-dimensionally in the fluid channel of the support unit, the sensing unit being surface-treated with a reactive material that is to react with the biomaterial flowing through the fluid channel.

2. The biosensor of claim 1, wherein the support unit comprises:
a substrate; and
an insulating layer disposed between the substrate and the sensing unit.

3. The biosensor of claim 2, wherein the substrate is formed of a material selected from the group consisting of monocrystalline silicon, glass, and plastic.

4. The biosensor of claim 2, wherein the support unit comprises a Silicon-On-Insulator (SOI) substrate.

5. The biosensor of claim 1, wherein the support unit has a flat-plate topside on which the sensing unit is disposed.

6. The biosensor of claim 1, wherein the sensing unit has a center portion that is superimposed on the fluid channel and a side portion that is not superimposed on the fluid channel, the center portion being smaller in width than the side portion.

7. The biosensor of claim 1, wherein the sensing unit is formed of a material whose electrical characteristics change depending on an external electric field.

8. The biosensor of claim 1, wherein the sensing unit is formed of a material selected from the group consisting of crystalline silicon, amorphous silicon, and doped silicon.

9. The biosensor of claim 1, wherein the sensing unit is provided in plurality and the sensing units are disposed across the fluid channel.

10. The biosensor of claim 1, wherein the fluid channel of the support unit is provided in plurality.

11. The biosensor of claim 10, wherein at least one of the sensing units is disposed across each of the fluid channels.

12. The biosensor of claim 1, further comprising a plurality of electrodes for connecting the sensing unit to an external device.

13. The biosensor of claim 12, wherein the electrodes are disposed on the sensing unit in such a way that the electrodes are not superimposed on the fluid channel.

14. A biosensing apparatus comprising:
a chamber having an inlet through which a fluid containing a biomaterial enters and an outlet through which the fluid exits; and
a plurality of biosensors inserted and fixed in the chamber, each of the biosensors including:
a support unit having a fluid channel through which a fluid containing a biomaterial flows; and
a sensing unit disposed on the support unit in such a way that the sensing unit is exposed three-dimensionally in the fluid channel of the support unit, the sensing unit being surface-treated with a reactive material that is to react with the biomaterial flowing through the fluid channel.

15. The biosensing apparatus of claim 14, further comprising a connecting member for connecting the neighboring biosensors.

16. The biosensing apparatus of claim 15, wherein the connecting member has the same periphery as the biosensor.

17. The biosensing apparatus of claim 15, wherein the connecting member has a through hole at a portion facing the inlet and the outlet.

18. The biosensing apparatus of claim 15, wherein the connecting member is formed of an adhesive material or comprises a structure that is surface-treated with an adhesive material.

19. The biosensing apparatus of claim 14, wherein the inlet and the outlet are disposed to face each other.

20. The biosensing apparatus of claim 14, wherein the inlet and the outlet are disposed to face the fluid channel of the biosensor.

21. The biosensing apparatus of claim 14, wherein the sensing units of the biosensors are surface-treated with different reactive materials.

22. A method for fabricating a biosensor, comprising the steps of:
forming an insulating layer on a top surface of a substrate;
depositing a sensing unit material on the insulating layer;
forming an etch barrier layer on a bottom surface of the substrate;
etching the etch barrier layer to expose a portion of the bottom surface of the substrate;
etching the substrate and the insulating layer using the etch barrier layer as an etching mask, to form a fluid channel exposing a portion of the sensing unit material; and
etching the sensing unit material to form a sensing unit intersecting the fluid channel.

23. The method of claim 22, further comprising, after the step of forming the sensing unit, the step of forming an electrode on a portion of the sensing unit which is not superimposed on the fluid channel.

24. The method of claim 23, further comprising, after the step of forming the electrode, the step of flowing a reactive material through the fluid channel such that the reactive material is adsorbed onto the sensing unit.

25. The method of claim 22, wherein the substrate is formed of a material selected from the group consisting of monocrystalline silicon, glass, and plastic.

26. The method of claim 22, wherein the sensing unit has a center portion that is superimposed on the fluid channel and a side portion that is not superimposed on the fluid channel, the center portion being smaller in width than the side portion.

27. The method of claim 22, wherein the sensing unit is formed of a material whose electrical characteristics change depending on an external electric field.

28. The method of claim 22, wherein the sensing unit is formed of a material selected from the group consisting of crystalline silicon, amorphous silicon, and doped silicon.
